(19) United States
(12) Patent Application Publication
(10) Pub. No.: US 2011/0146781 A1
(43) Pub. Date: Jun. 23, 2011

(54) PROCESS OF FORMING A GRID CATHODE ON THE FRONT-SIDE OF A SILICON WAFER

(75) Inventors: Giovanna Laudisio, Bristol (GB); Kenneth Warren Hang, Hillsborough, NC (US); Richard John Sheffield Young, Somerset (GB)

(73) Assignee: E.I. DU PONT DE NEMOURS AND COMPANY, Wilmington, DE (US)

(21) Appl. No.: 12/822,466

(22) Filed: Jun. 24, 2010

Related U.S. Application Data
(60) Provisional application No. 61/220,633, filed on Jun. 26, 2009.

(51) Int. Cl. H01L 31/0224; H01L 31/18

(52) U.S. Cl. 136/256; 438/72; 257/E31.124; 257/E31.119

(57) ABSTRACT

A process for the production of a grid cathode on the front-side of a silicon wafer by applying and firing a metal paste on the silicon wafer in a front-side grid electrode pattern to form a seed grid cathode and subsequently subjecting the silicon wafer to a LIP process, wherein the metal paste comprises an organic vehicle and an inorganic content comprising (a) 90 to 98 wt.-% of at least one electrically conductive metal powder selected from the group consisting of nickel, copper and silver, and (b) 0.25 to 8 wt.-% of at least one glass frit selected from the group consisting of glass frits containing 47.5 to 64.3 wt.-% of PbO, 23.8 to 32.2 wt.-% of SiO₂, 3.9 to 5.4 wt.-% of Al₂O₃, 2.8 to 3.8 wt.-% of TiO₂ and 6.9 to 9.3 wt.-% of B₂O₃.

### FIELD OF THE INVENTION

The present invention is directed to a process of forming a grid cathode on the front-side of a silicon wafer.

### TECHNICAL BACKGROUND OF THE INVENTION

A conventional solar cell structure with a p-type base has a negative electrode that is typically on the front-side or illuminated side of the cell and a positive electrode on the back-side. It is well known that radiation of an appropriate wavelength falling on a p-n junction of a semiconductor body serves as a source of external energy to generate electron-hole pairs in that body. The potential difference that exists at a p-n junction, causes holes and electrons to move across the junction in opposite directions, thereby giving rise to flow of an electric current that is capable of delivering power to an external circuit. Most solar cells are in the form of a silicon wafer that has been metallized, i.e., provided with metal contacts which are electrically conductive.

Most electric power-generating solar cells currently used are silicon solar cells. Electrodes in particular are made by using a method such as screen printing from metal pastes.

The production of a silicon solar cell typically starts with a p-type silicon substrate in the form of a silicon wafer on which an n-type diffusion layer of the reverse conductivity type is formed by the thermal diffusion of phosphorus (P) or the like. Phosphorus oxychloride (POCl₃) is commonly used as the gaseous phosphorus diffusion source, other liquid sources are phosphoric acid and the like. In the absence of any particular modification, the diffusion layer is formed over the entire surface of the silicon substrate. The p-n junction is formed where the concentration of the p-type dopant equals the concentration of the n-type dopant; conventional cells that have the p-n junction close to the illuminated side, have a junction depth between 0.05 and 0.5 μm.

After formation of this diffusion layer excess surface glass is removed from the rest of the surfaces by etching with an acid such as hydrofluoric acid.

Next, an ARC layer (antireflective coating layer) of TiOₓ, SiOₓ, TiOₓ/SiOₓ, or, in particular, SiNₓ or Si₃N₄ is formed on the n-type diffusion layer to a thickness of between 0.05 and 0.1 μm by a process, such as, for example, plasma CVD (chemical vapor deposition).

A conventional solar cell structure with a p-type base typically has a negative grid electrode on the front-side of the cell and a positive electrode on the back-side. The grid electrode is typically applied by screen printing and drying a front-side silver paste (front electrode forming silver paste) on the ARC layer on the front-side of the cell. The front-side grid electrode is typically screen printed in a so-called H pattern which comprises (i) thin parallel finger lines (collector lines) and (ii) two busbars intersecting the finger lines at right angle. In addition, a back-side silver or silver/aluminum paste and an aluminum paste are screen printed (or some other application method) and successively dried on the back-side of the substrate. Normally, the back-side silver or silver/aluminum paste is screen printed onto the silicon wafer's back-side first as two parallel busbars or as rectangles (tabs) ready for soldering interconnection strings (presoldered copper ribbons). The aluminum paste is then printed in the bare areas with a slight overlap over the back-side silver or silver/aluminum. In some cases, the silver or silver/aluminum paste is printed after the aluminum paste has been printed. Firing is then typically carried out in a belt furnace for a period of 1 to 5 minutes with the wafer reaching a peak temperature in the range of 700 to 900° C. The front grid electrode and the back electrodes can be fired sequentially or cofired.

The aluminum paste is generally screen printed and dried on the back-side of the silicon wafer. The wafer is fired at a temperature above the melting point of aluminum to form an aluminum-silicon melt, subsequently, during the cooling phase, an epitaxially grown layer of silicon is formed that is doped with aluminum. This layer is generally called the back surface field (BSF) layer. The aluminum paste is transformed by firing from a dried state to an aluminum back electrode. The back-side silver or silver/aluminum paste is fired at the same time, becoming a silver or silver/aluminum back electrode. During firing, the boundary between the back-side aluminum and the back-side silver or silver/aluminum assumes an alloy state, and is connected electrically as well. The aluminum electrode accounts for most areas of the back electrode, owing in part to the need to form a p+ layer. A silver or silver/aluminum back electrode is formed over portions of the back-side (often as 2 to 6 mm wide busbars) as an electrode for interconnecting solar cells by means of pre-soldered copper ribbon or the like. In addition, the front-side silver paste printed as front-side grid electrode sinters and penetrates through the ARC layer during firing, and is thereby able to electrically contact the n-type layer. This type of process is generally called “firing through”.

The electrical efficiency of a silicon solar cell of the type described above can be increased by employing a so-called LIP (light-induced plating) process by which electrically conductive silver is deposited on the front-side grid electrode. During the LIP process the front-side grid electrode serves as a seed electrode which is electroplated with silver; see A. Mette et al., “Increasing the Efficiency of Screen-Printed Silicon Solar Cells by Light-Induced Silver Plating”, Photovoltaic Energy Conversion, Conference Record of the 2006 IEEE 4th World Conference on Volume 1, May 2006, pages 1056-1059. During the LIP process a silicon solar cell provided with a front-side seed grid cathode is immersed in a LIP bath, i.e. in an aqueous bath containing silver in cathodically depositable form. The front-side of the cell is illuminated and the negative potential created on the front-side causes silver to deposit on the seed grid cathode. At the same time the back-side of the cell is connected to an external power supply and a voltage bias is applied for compensating the positive potential created under illumination of the silicon wafer's front-side to prevent dissolution of the aluminum layer. A sacrificial electrode of silver is anodically connected to the external power supply for replenishing the LIP bath with the silver consumed from the LIP bath by the deposition process.

It has now been found that the electrical efficiency of a silicon solar cell provided with a front-side grid cathode made by applying and firing a seed grid cathode and depositing silver by LIP thereon can be further improved when the electrically conductive metal paste used for applying the seed grid cathode contains glass frit having a certain composition.

### SUMMARY OF THE INVENTION

The present invention relates to a process for the production of a grid cathode on the front-side of a silicon wafer having a p-type region, an n-type region, a p-n junction and an ARC layer on said front-side, comprising the steps:

(1) providing a silicon wafer having an ARC layer on its front-side,
(2) applying and drying a metal paste on the ARC layer on the front-side of the silicon wafer in a front-side grid electrode pattern, and
(3) firing the metal paste to form a seed grid cathode, and
(4) depositing silver on the seed grid cathode by subjecting the silicon wafer provided with the seed grid cathode to a LIP process, wherein the metal paste comprises an organic vehicle and an inorganic content comprising (a) 90 to 98 wt.-% of at least one electrically conductive metal powder selected from the group consisting of nickel, copper and silver, and (b) 0.25 to 8 wt.-% of at least one glass frit selected from the group consisting of glass frits containing 47.5 to 64.3 wt.-% of PbO, 23.8 to 32.2 wt.-% of SiO₂, 3.9 to 5.4 wt.-% of Al₂O₃, 2.8 to 3.8 wt.-% of TiO₂ and 6.9 to 9.3 wt.-% of B₂O₃.

In the description and the claims the terms “seed grid cathode” and “grid cathode” are used to draw a clear distinction between the seed grid cathode obtained on completion of process step (3) and the grid cathode obtained on completion of process step (4), i.e. the grid cathode produced by the process of the present invention.

### DETAILED DESCRIPTION OF THE EMBODIMENTS

In step (1) of the process of the present invention a silicon wafer having an ARC layer on its front-side is provided. The silicon wafer is a conventional mono- or polycrystalline silicon wafer as is conventionally used for the production of silicon solar cells; it has a p-type region, an n-type region and a p-n junction. The silicon wafer has an ARC layer, for example, of TiOₓ, SiOₓ, TiOₓ/SiOₓ, or, in particular, SiNₓ or Si₃N₄ on its front-side. Such silicon wafers are well known to the skilled person; for brevity reasons reference is made to the section “TECHNICAL BACKGROUND OF THE INVENTION”. The silicon wafer may already be provided with the conventional back-side metallizations, i.e. with a back-side aluminum paste and a back-side silver or back-side silver/aluminum paste as described above in the section “TECHNICAL BACKGROUND OF THE INVENTION”. Application of the back-side metal pastes (including the back-side aluminum paste) may be carried out before or after the front-side seed grid cathode is finished in step (3). Preferentially, the back-side metal pastes (including the back-side aluminum paste) are applied and fired before process step (4) is carried out. The back-side metal pastes (including the back-side aluminum paste) may be individually fired or cofired or even be cofired with the front-side metal paste applied on the ARC layer in step (2).

In step (2) of the process of the present invention a metal paste is applied on the ARC layer on the front-side of the silicon wafer in a front-side grid electrode pattern.

The metal paste is a thick film conductive composition with fire-through capability, i.e. it fires through an ARC layer making electrical contact with the surface of the silicon substrate.

The metal paste comprises an organic vehicle and an inorganic content comprising (a) 90 to 98 wt.-% of at least one electrically conductive metal powder selected from the group consisting of nickel, copper and silver, and (b) 0.25 to 8 wt.-% of at least one glass frit selected from the group consisting of glass frits containing 47.5 to 64.3 wt.-% of PbO, 23.8 to 32.2 wt.-% of SiO₂, 3.9 to 5.4 wt.-% of Al₂O₃, 2.8 to 3.8 wt.-% of TiO₂ and 6.9 to 9.3 wt.-% of B₂O₃.

The metal paste comprises an organic vehicle. A wide variety of inert viscous materials can be used as organic vehicle. The organic vehicle may be one in which the particulate constituents (electrically conductive metal powder, glass frit, optionally present other particulate inorganic components) are dispersible with an adequate degree of stability. The properties, in particular, the rheological properties, of the organic vehicle may be such that they lend good application properties to the metal paste, including: stable dispersion of insoluble solids, appropriate viscosity and thixotropy for the application, appropriate wettability of the ARC layer on the front-side of the silicon wafer and of the paste solids, a good drying rate, and good firing properties. The organic vehicle used in the metal paste may be a nonaqueous inert liquid. The organic vehicle may be an organic solvent or an organic solvent mixture; in an embodiment, the organic vehicle may be a solution of organic polymer(s) in organic solvent(s). Use can be made of any of various organic vehicles, which may or may not contain thickeners, stabilizers and/or other common additives. In an embodiment, the polymer used as constituent of the organic vehicle may be ethyl cellulose. Other examples of polymers which may be used alone or in combination include ethylhydroxyethyl cellulose, wood rosin, phenolic resins and poly(meth)acrylates of lower alcohols. Examples of suitable organic solvents comprise ester alcohols and terpenes such as alpha- or beta-terpineol or mixtures thereof with other solvents such as kerosene, dibutylphthalate, diethylene glycol butyl ether, diethylene glycol butyl ether acetate, hexylene glycol and high boiling alcohols. In addition, volatile organic solvents for promoting rapid hardening after application of the metal paste can be included in the organic vehicle. Various combinations of these and other solvents may be formulated to obtain the viscosity and volatility requirements desired.

The ratio of organic vehicle in the metal paste to the inorganic content (inorganic components; electrically conductive metal powder plus glass frit plus optionally present other inorganic additives) is dependent on the application method of the metal paste and the kind of organic vehicle used, and it can vary. Usually, the metal paste will contain 40 to 95 wt.-% of inorganic components and 5 to 60 wt.-% of organic vehicle.

The inorganic content of the metal paste comprises (a) 90 to 98 wt.-% of at least one electrically conductive metal powder selected from the group consisting of nickel, copper and silver, and (b) 0.25 to 8 wt.-% of at least one glass frit selected from the group consisting of glass frits containing 47.5 to 64.3 wt.-% of PbO, 23.8 to 32.2 wt.-% of SiO₂, 3.9 to 5.4 wt.-% of Al₂O₃, 2.8 to 3.8 wt.-% of TiO₂ and 6.9 to 9.3 wt.-% of B₂O₃.

In an embodiment, the inorganic content of the metal paste comprises (a) 92 to 98 wt.-% of at least one electrically conductive metal powder selected from the group consisting of nickel, copper and silver, and (b) 1.5 to 4 wt.-% of at least one glass frit selected from the group consisting of glass frits containing 47.5 to 64.3 wt.-% of PbO, 23.8 to 32.2 wt.-% of SiO₂, 3.9 to 5.4 wt.-% of Al₂O₃, 2.8 to 3.8 wt.-% of TiO₂ and 6.9 to 9.3 wt.-% of B₂O₃.

It is possible that the inorganic content of the metal paste comprises further inorganic components other than components (a) and (b), as can be calculated from the weight percentages of components (a) and (b). Examples of such other inorganic components comprise solid inorganic oxides or compounds capable of forming solid inorganic oxides during firing of the metal paste. Examples of said solid inorganic oxides include silicon dioxide, zinc oxide, magnesium oxide, calcium oxide and lithium oxide. In general, the inorganic content of the metal paste comprises no other glass frit than the at least one glass frit selected from the group consisting of glass frits containing 47.5 to 64.3 wt.-% of PbO, 23.8 to 32.2 wt.-% of SiO₂, 3.9 to 5.4 wt.-% of Al₂O₃, 2.8 to 3.8 wt.-% of TiO₂ and 6.9 to 9.3 wt.-% of B₂O₃.

The metal paste comprises at least one electrically conductive metal powder selected from the group consisting of silver, copper and nickel. Silver powder is preferred. The metal or silver powder may be uncoated or at least partially coated with a surfactant. The surfactant may be selected from, but is not limited to, stearic acid, palmitic acid, lauric acid, oleic acid, capric acid, myristic acid and linolic acid and salts thereof, for example, ammonium, sodium or potassium salts.

The average particle size of the electrically conductive metal powder or, in particular, silver powder is in the range of, for example, 0.2 to 5 μm.

In the description and the claims the term “average particle size” is used. It means the mean particle diameter (d50) determined by means of laser scattering. All statements made in the present description and the claims in relation to average particle sizes relate to average particle sizes of the relevant materials as are present in the metal paste.

In general the metal paste comprises only the at least one electrically conductive metal powder selected from the group consisting of silver, copper, and nickel. However, it is possible to replace a small proportion of the electrically conductive metal selected from the group consisting of silver, copper and nickel by one or more other particulate metals. The proportion of such other particulate metal(s) is, for example, 0 to 10 wt. %, based on the total of particulate metals contained in the metal paste.

As already mentioned, the metal paste comprises at least one glass frit as inorganic binder. The one or more glass frits are selected from the group consisting of glass frits containing 47.5 to 64.3 wt.-% of PbO, 23.8 to 32.2 wt.-% of SiO₂, 3.9 to 5.4 wt.-% of Al₂O₃, 2.8 to 3.8 wt.-% of TiO₂ and 6.9 to 9.3 wt.-% of B₂O₃. In an embodiment, the one or more glass frits are selected from the group consisting of glass frits containing 50.3 to 61.5 wt.-% of PbO, 25.2 to 30.8 wt.-% of SiO₂, 4.2 to 5.2 wt.-% of Al₂O₃, 3.0 to 3.6 wt.-% of TiO₂ and 7.3 to 8.9 wt.-% of B₂O₃. In another embodiment, the one or more glass frits are selected from the group consisting of glass frits containing 53.1 to 58.7 wt.-% of PbO, 26.6 to 29.4 wt.-% of SiO₂, 4.5 to 4.9 wt.-% of Al₂O₃, 3.1 to 3.5 wt.-% of TiO₂ and 7.7 to 8.5 wt.-% of B₂O₃. As can be calculated from the weight percentages of PbO, SiO₂, Al₂O₃, TiO₂ and B₂O₃, the latter do not necessarily add up to 100 wt.-%; however, in an embodiment, the total of the weight percentages of PbO, SiO₂, Al₂O₃, TiO₂ and B₂O₃ is 100 wt.-%. In case the weight percentages of PbO, SiO₂, Al₂O₃, TiO₂ and B₂O₃ do not total 100 wt.-%, the missing wt.-% may in particular be contributed by one or more other oxides.

The average particle size of the at least one glass frit is in the range of, for example, 0.5 to 4 μm.

The preparation of the glass frit is well known and consists, for example, in melting together the constituents of the glass in the form of the oxides of the constituents and pouring such molten composition into water to form the frit. As is well known in the art, heating may be conducted to a peak temperature of, for example, 1300 to 1450° C. and for a time such that the melt becomes entirely liquid and homogeneous, for example, 0.5 to 1.5 hours.

The glass may be milled in a ball mill with water or inert low viscosity, low boiling point organic liquid to reduce the particle size of the frit and to obtain a frit of substantially uniform size. It may then be settled in water or said organic liquid to separate fines and the supernatant fluid containing the fines may be removed. Other methods of classification may be used as well.

The metal paste is a viscous composition, which may be prepared by mechanically mixing the electrically conductive metal powder and the glass frit and the other optionally present solid inorganic components with the organic vehicle. In an embodiment, the manufacturing method power mixing, a dispersion technique that is equivalent to the traditional roll milling, may be used; roll milling or other mixing technique can also be used.

The metal paste can be used as such or may be diluted, for example, by the addition of additional organic solvent(s); accordingly, the weight percentage of all the other constituents of the metal paste may be decreased. In step (2) of the process of the present invention the metal paste is applied on the ARC layer on the front-side of the silicon wafer in a front-side grid electrode pattern. Examples of metal paste application methods include pen-writing and printing methods, such as, for example, jet printing, stencil printing and screen printing. The front-side grid electrode may comprise (i) thin parallel finger lines and (ii) two or more parallel busbars intersecting the finger lines at right angle. In an embodiment, the grid pattern is an H pattern with two parallel busbars. The parallel finger lines may have a distance between each other of, for example, 2 to 5 mm, a dry layer thickness of, for example, 3 to 30 μm and a width of, for example, 40 to 200 μm. The busbars may have a dry layer thickness of, for example, 10 to 50 μm and a width of, for example, 1 to 3 mm. After its application, the metal paste is dried, for example, for a period of 1 to 100 minutes with the silicon wafer reaching a peak temperature in the range of 100 to 300° C. Drying can be carried out making use of, for example, belt, rotary or stationary driers, in particular, IR (infrared) belt driers.

In step (3) of the process of the present invention the dried metal paste is fired to form a seed grid cathode. The firing of step (3) may be performed, for example, for a period of 1 to 5 minutes with the silicon wafer reaching a peak temperature in the range of 700 to 900° C. The firing can be carried out making use of, for example, single or multi-zone belt furnaces, in particular, multi-zone IR belt furnaces. The firing may happen in an inert gas atmosphere or in the presence of oxygen, for example, in the presence of air. During firing the organic substance including non-volatile organic material and the organic portion not evaporated during the drying may be removed, i.e. burned and/or carbonized, in particular, burned. The organic substance removed during firing includes organic solvent(s), optionally present organic polymer(s), optionally present organic additive(s) and organic moieties of optionally present metal-organic compounds. There is a further process taking place during firing, namely sintering of the glass frit with the electrically conductive metal powder. The metal paste etches the ARC layer and fires through making electrical contact with the silicon substrate.

As already mentioned, firing may be performed as so-called cofiring together with back-side metal pastes that have been applied to the silicon wafer.

The seed grid cathode so formed in step (3) of the process of the present invention is electrically conductive and allows for successfully performing subsequent process step (4); i.e. the seed grid cathode can be electroplated with silver during process step (4) to form the front-side grid cathode.

In step (4) of the process of the present invention the silicon wafer provided with the seed grid cathode is subjected to a LIP process thereby depositing silver on the seed grid cathode. To this end the silicon wafer is immersed into a LIP bath and the front-side of the immersed silicon wafer with the seed grid cathode thereon is illuminated. Regarding the connection of the silicon wafer's back-side to an external power supply and the measures taken to keep the LIP bath's silver content constant, reference is made to the section “TECHNICAL BACKGROUND OF THE INVENTION”. The LIP bath is an aqueous bath containing silver in cathodically depositable form. Typically, the LIP bath has an alkaline pH (measured by making use of a conventional pH meter) in the range of, for example, 8 to 11, in particular, 9 to 10.5. For example, halogen or fluorescent lamps may be used for illumination purposes. The illumination is carried out, until the desired amount of silver has been deposited from the LIP bath on the seed grid cathode, i.e. until the grid cathode has been formed. During this step (4) of the process of the invention the silver deposition results in growth of the grid obtained in step (3); for example, in case of a grid comprising parallel finger lines and two or more parallel busbars intersecting the finger lines at right angle, the layer thickness of the fingers may increase by, for example, 5 to 30 μm, their width by, for example, 10 to 100 μm and the layer thickness of the busbars by, for example, 5 to 30 μm. The growth of the busbars in width is hardly worth mentioning given their starting width of, for example, 1 to 3 mm.

After the LIP process has been finished, the silicon wafer provided with the front-side grid cathode is removed from the LIP bath, rinsed with water to remove LIP bath residues and dried.

The aforementioned further improvement of the electrical efficiency of silicon solar cells provided with a front-side grid cathode made by the process of the present invention is not simply a result of carrying out the LIP process step (4). Without being bound by theory and although not investigated in sufficient detail, it is believed that the composition of the glass frit contained in the metal paste used for the application of the front-side seed grid cathode is key. It is believed that said glass frit composition allows for a well-balanced ratio between the deposition of silver and dissolution of glass during the LIP process step (4) with the result of forming a grid cathode with a comparably dense structure with good electrical conductivity and low contact resistance with the silicon substrate.

What is claimed is:

1. A process for the production of a grid cathode on the front-side of a silicon wafer having a p-type region, an n-type region, a p-n junction and an ARC layer on said front-side, comprising the steps:
(1) providing a silicon wafer having an ARC layer on its front-side,
(2) applying and drying a metal paste on the ARC layer on the front-side of the silicon wafer in a front-side grid electrode pattern, and
(3) firing the metal paste to form a seed grid cathode, and
(4) depositing silver on the seed grid cathode by subjecting the silicon wafer provided with the seed grid cathode to a LIP process,
wherein the metal paste comprises an organic vehicle and an inorganic content comprising (a) 90 to 98 wt.-% of at least one electrically conductive metal powder selected from the group consisting of nickel, copper and silver, and (b) 0.25 to 8 wt.-% of at least one glass frit selected from the group consisting of glass frits containing 47.5 to 64.3 wt.-% of PbO, 23.8 to 32.2 wt.-% of SiO₂, 3.9 to 5.4 wt.-% of Al₂O₃, 2.8 to 3.8 wt.-% of TiO₂ and 6.9 to 9.3 wt.-% of B₂O₃.

2. The process of claim 1, wherein the at least one glass frit is selected from the group consisting of glass frits containing 50.3 to 61.5 wt.-% of PbO, 25.2 to 30.8 wt.-% of SiO₂, 4.2 to 5.2 wt.-% of Al₂O₃, 3.0 to 3.6 wt.-% of TiO₂ and 7.3 to 8.9 wt.-% of B₂O₃.

3. The process of claim 1, wherein the at least one glass frit is selected from the group consisting of glass frits containing 53.1 to 58.7 wt.-% of PbO, 26.6 to 29.4 wt.-% of SiO₂, 4.5 to 4.9 wt.-% of Al₂O₃, 3.1 to 3.5 wt.-% of TiO₂ and 7.7 to 8.5 wt.-% of B₂O₃.

4. The process of claim 1, wherein the total of the weight percentages of PbO, SiO₂, Al₂O₃, TiO₂ and B₂O₃ is 100 wt.-%.

5. The process of claim 1, wherein the inorganic content comprises (a) 92 to 98 wt.-% of the at least one electrically conductive metal powder and (b) 1.5 to 4 wt.-% of the at least one glass frit.

6. The process of claim 1, wherein the at least one electrically conductive metal powder is silver powder.

7. The process of claim 1, wherein the metal paste contains 40 to 95 wt.-% of inorganic components and 5 to 60 wt.-% of organic vehicle.

8. The process of claim 1, wherein the metal paste is applied by a method selected from the group consisting of pen-writing, jet printing, stencil printing and screen printing.

9. The process of claim 1, wherein the front-side grid electrode pattern comprises (i) thin parallel finger lines and (ii) two or more parallel busbars intersecting the finger lines at right angle.

10. The process of claim 1, wherein the LIP process comprises immersing the silicon wafer into a LIP bath and illuminating the front-side of the immersed silicon wafer with the seed grid cathode thereon.

11. The process of claim 1, wherein the LIP bath is an aqueous bath having a pH of 8 to 11 and containing silver in cathodically depositable form.

12. A front-side grid cathode produced according to the process of claim 1.

13. A silicon solar cell comprising a silicon wafer having an ARC layer on its front-side and the front-side grid cathode of claim 12.
